(19) United States
(12) Patent Application Publication
(10) Pub. No.: US 2026/0129970 A1
(43) Pub. Date: May 7, 2026

(54) SEMICONDUCTOR STRUCTURE AND MANUFACTURING METHOD THEREOF

(71) Applicant: TAIWAN SEMICONDUCTOR MANUFACTURING COMPANY LTD., HSINCHU (TW)

(72) Inventor: HUNG-TE LIN, HSINCHU COUNTY (TW)

(21) Appl. No.: 18/938,321

(22) Filed: Nov. 6, 2024

(51) Int. Cl. H01L 27/12; H01L 21/762; H01L 21/768

(52) U.S. Cl. CPC H10D 86/201; H10P 90/1906; H10P 90/1908; H10W 10/014; H10W 10/061; H10W 10/17; H10W 10/181; H10W 20/066

(57) ABSTRACT

A semiconductor structure includes a substrate having a first doping type, a first conductive structure disposed within the substrate and having a bottom portion and a sidewall portion disposed over and coupled to the bottom portion, a first isolation layer disposed under the first conductive structure and within the substrate, and a semiconductor device disposed over the first conductive structure and including an oxide layer disposed over a first surface of the substrate. The first conductive structure is partially enclosed by the oxide layer and the first isolation layer, at least a portion of the semiconductor device is surrounded by the sidewall portion of the first conductive structure, and the semiconductor device is separated from the first conductive structure.

### BACKGROUND

The semiconductor industry has experienced rapid growth due to ongoing improvements in integration density of a variety of electrical components. To accommodate miniaturized scales of many semiconductor devices, various technologies and applications have been developed for wafer-level packaging, involving greater numbers of different components with different functions.

As semiconductor technologies continually advance, embedding of electrical components into a semiconductive substrate has emerged as an effective approach to further reducing a physical size of a semiconductor device. The electrical component is at least partially embedded within the semiconductive substrate in order to minimize an amount of space occupied above the semiconductive substrate. Such embedding processes utilize sophisticated techniques, and improvements are desired.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a semiconductor structure in accordance with some embodiments of the present disclosure.

FIGS. 2 and 3 are schematic cross-sectional views taken along a line A-A' in FIG. 1.

FIG. 4 is a cross-sectional view of a semiconductor structure in accordance with some embodiments of the present disclosure.

FIGS. 5, 6 and 7 are cross-sectional views of a portion of a semiconductor structure in accordance with some embodiments of the present disclosure.

FIG. 8 is a schematic top view of a semiconductor structure in accordance with some embodiments of the present disclosure.

FIG. 9 is a schematic cross-sectional view taken along a line B-B' in FIG. 8.

FIG. 10 is a flow diagram of a method of manufacturing a semiconductor structure in accordance with some embodiments of the present disclosure.

FIG. 11 is a flow diagram of a method of manufacturing a semiconductor structure in accordance with some embodiments of the present disclosure.

FIGS. 12 to 24 are cross-sectional views of one or more stages of a method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal variation found in the respective testing measurements. Also, as used herein, the terms "substantially," "approximately" and “about” generally mean within a value or range that can be contemplated by people having ordinary skill in the art. Alternatively, the terms "substantially," "approximately" and "about" mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms "substantially," "approximately" or "about." Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In the present disclosure, a semiconductor structure and a method of manufacturing a semiconductor structure are provided. The semiconductor structure includes a substrate having a surface; a conductive structure disposed within the substrate and having a first bottom portion, a first sidewall portion disposed over and coupled to the first bottom portion, and a first upper portion coupled to the first sidewall portion and exposed through the surface; and a semiconductor device disposed over and electrically connected to the conductive structure. The first sidewall portion is disposed between the first bottom portion and the first upper portion, and at least a portion of the semiconductor device is surrounded by the first sidewall portion of the conductive structure in a plan view. An electrical signal generated by the semiconductor device can be transmitted evenly through the conductive structure.

In some embodiments, a method of manufacturing a semiconductor structure includes providing a substrate having a surface; forming a recess on the surface of the substrate; forming a conductive structure within and conformal to the recess; forming a semiconductor material layer in the recess and over the conductive structure; doping the semiconductor material layer to form a doped semiconductor material layer; and forming a semiconductor device over the doped semiconductor material layer, wherein the semiconductor device is electrically connected to the conductive structure. At least a portion of the semiconductor device is surrounded by the conductive structure.

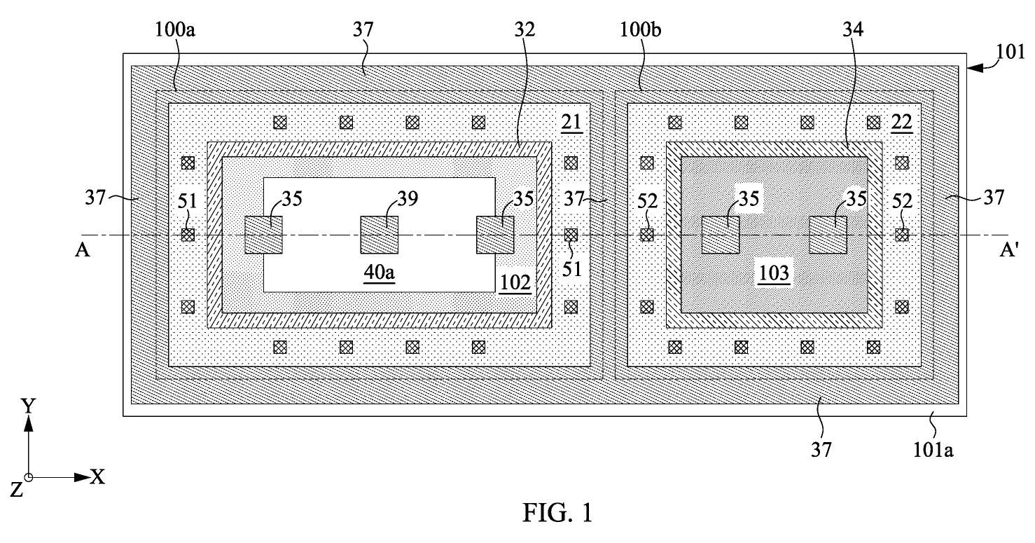

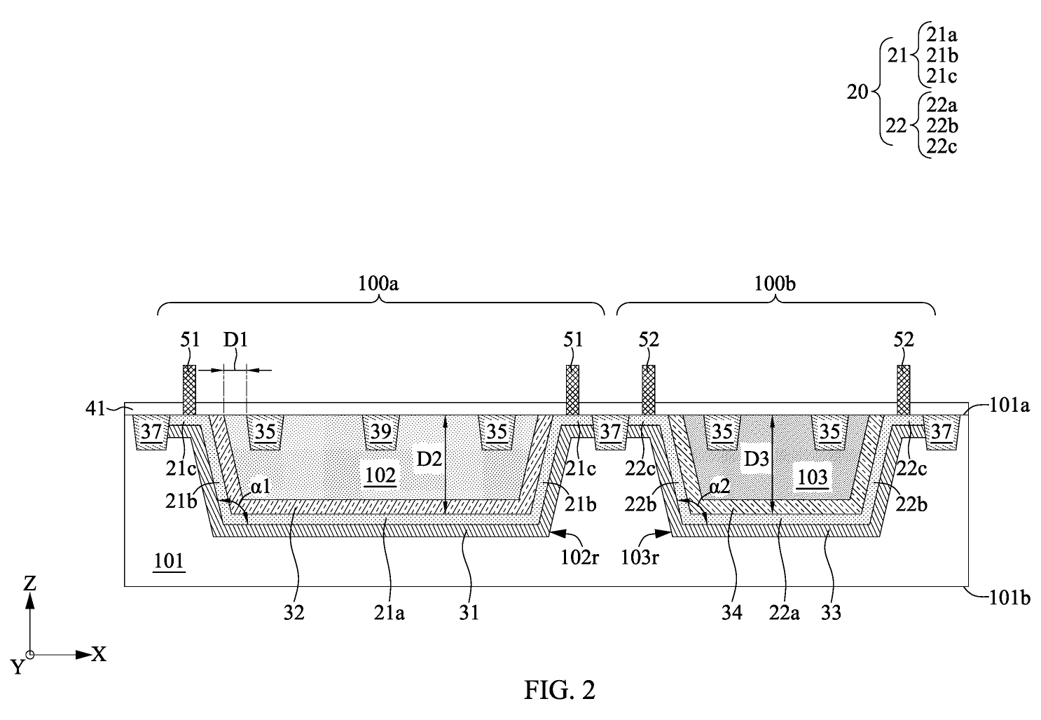

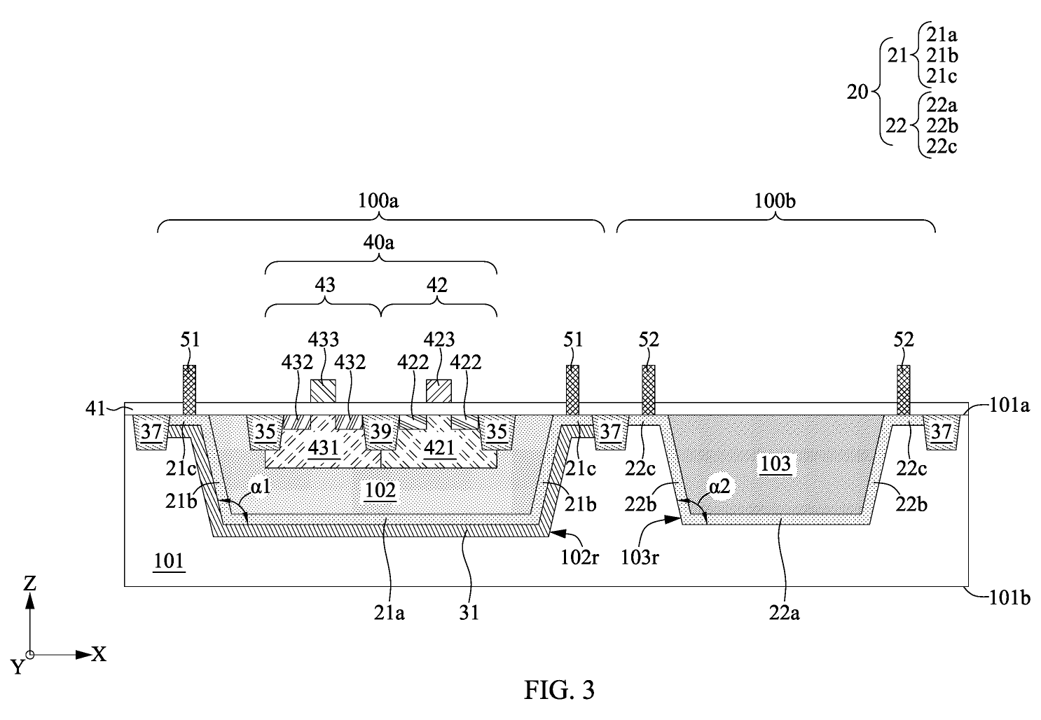

FIG. 1 is a schematic top view of a semiconductor structure according to aspects of the present disclosure in some embodiments. FIGS. 2 and 3 are schematic cross-sectional views taken along a line A-A' in FIG. 1. Referring to FIGS. 1, 2 and 3, a plurality of semiconductor structures 100a and 100b are disposed on a first surface 101a of a substrate 101, and each of the semiconductor structures 100a and 100b may include a first semiconductor device 40a. A conductive structure 20 is disposed within the substrate 101 and has a portion exposed through the first surface 101a of the substrate 101. In some embodiments, the semiconductor structure 100a is a chip, a package or a part of a chip or a package. In some embodiments, the semiconductor structure 100a is a part of a system on integrated circuit (SoIC) structure, a chip on wafer on substrate (CoWoS) structure, an integrated fan out (InFO) structure, or the like.

In some embodiments, the substrate 101 is a part of a substrate comprising at least one of an epitaxial layer, a single crystalline semiconductor material such as, but not limited to, at least one of Si, Ge, SiGe, InGaAs, GaAs, InSb, GaP, GaSb, InAlAs, GaSbP, GaAsSb, or InP, a silicon-on-insulator (SOI) structure, a wafer, and a die formed from a wafer. In some embodiments, the substrate 101 is a semiconductor wafer. In some embodiments, the substrate 101 comprises at least one of crystalline silicon and other suitable materials. Other structures and/or configurations of the substrate 101 are within the scope of the present disclosure.

The substrate 101 includes the first surface 101a and a second surface 101b opposite to the first surface 101a. In some embodiments, the first surface 101a is a front side or an active side with several electrical components disposed thereon. In some embodiments, the second surface 101b is a back side or an inactive side from which electrical components are absent.

In some embodiments, the semiconductor structure 100a includes a first conductive structure 21 of the conductive structure 20 and a semiconductor device 40a disposed over the first conductive structure 21. The first conductive structure 21 is configured to transmit a uniform signal to the first semiconductor material layer 102. In some embodiments, a plurality of first semiconductor devices 40a are disposed over the first conductive structure 21.

The first conductive structure 21 is disposed under the first semiconductor device 40a and includes a first bottom portion 21a and a first sidewall portion 21b disposed over and coupled to the first bottom portion 21a. In some embodiments, the first bottom portion 21a extends along a first direction X parallel to the first surface 101a. The first bottom portion 21a extends in the horizontal plane (i.e., the X-Y plane as shown in FIG. 1). The first bottom portion 21a is disposed under the first semiconductor device 40a. In some embodiments, the first conductive structure 21 has a rectangular shape. Although the first conductive structure 21 of the semiconductor structure 100a is shown as being rectangular in FIG. 1, in other embodiments the first conductive structure 21 can comprise other shapes, such as hexagon, octagon, circle, or others. In some embodiments, the first bottom portion 21a has a shape conformal to the shape of the first conductive structure 21. In some embodiments, the first sidewall portion 21b encircles the first bottom portion 21a.

The first sidewall portion 21b extends upward from a perimeter of the first bottom portion 21a and toward the first surface 101a of the semiconductor substrate 101. In some embodiments, the first sidewall portion 21b reaches the first surface 101a of the semiconductor substrate 101. In some embodiments, the first sidewall portion 21b extends upward from two opposite sides of the first bottom portion 21a. In some embodiments, the first sidewall portion 21b extends upward from an entirety of the perimeter of the first bottom portion 21a, and the first sidewall portion 21b surrounds the first semiconductor device 40a in a plan view. The first sidewall portion 21b is oriented at a first angle α1 respective to the plane of the first bottom portion 21a, as shown in FIGS. 2 and 3. In some embodiments, the first angle α1 between the first bottom portion 21a and first sidewall portion 21b is close to 90°. In some embodiments, the first sidewall portion 21b is at an obtuse angle respective to the first bottom portion 21a, that is, the first angle α1 is greater than 90°. An acute angle (i.e., an angle less than 90°) is also contemplated for the first angle α1. In some embodiments, the first sidewall portion 21b is at an angle of between 85° and 160° respective to the plane of the first bottom portion 21a. Formation of the first sidewall portion 21b may be difficult if the first angle α1 is too small. The first conductive structure 21 may occupy too much area if the first angle α1 is too large. It should also be noted that the first sidewall portion 21b may not be perfectly straight, e.g., the first sidewall portion 21b may have some curvature (not shown). Likewise, while the first bottom portion 21a is illustrated as being planar, some curvature of the first bottom portion 21a may also be present in some embodiments.

In some embodiments, the first conductive structure 21 further includes a first upper portion 21c coupled to the first sidewall portion 21b. The first sidewall portion 21b is disposed between the first bottom portion 21a and the first upper portion 21c, and the first upper portion 21c is in contact with a dielectric layer, such as an oxide layer 41 disposed on the first surface 101a. In some embodiments, the first upper portion 21c extends from the first sidewall portion 21b and away from the first semiconductor device 40a along the first direction X. In some embodiments, a top surface of the first upper portion 21c is coplanar with the first surface 101a. In some embodiments, the first upper portion 21c encircles the first bottom portion 21a in a plan view.

In some embodiments, the first conductive structure 21 is integral and continuous. In some embodiments, the first bottom portion 21a and the first sidewall portion 21b are integral and continuous, and an interface between the first bottom portion 21a and the first sidewall portion 21b is absent. In some embodiments, the first bottom portion 21a, the first sidewall portion 21b and the first upper portion 21c are integral and continuous. In some embodiments, the first conductive structure 21 includes segments.

In some embodiments, the first conductive structure 21 includes several conductive layers. In some embodiments, a periphery of the first conductive structure 21 is isolated from the substrate 101. The first conductive structure 21 may include a conductive material such as copper, titanium nitride (TiN), metal silicide, polysilicon, or the like. In some embodiments, the first conductive structure 21 includes nickel silicide (NiSi) or cobalt silicide (CoSi).

The first conductive structure 21 is electrically coupled to a first contact 51 disposed over the first conductive structure 21. In some embodiments, the first contact 51 is disposed over the first upper portion 21c of the first conductive structure 21, and the first contact 51 extends through at least the oxide layer 41. In some embodiments, the first semiconductor device 40a is surrounded by a plurality of first contacts 51.

For ease of illustration, the first contact 51 is illustrated in simplified form. In some embodiments, the first contact 51 comprises a barrier layer, a seed layer, a metal fill layer, and/or other suitable layers. In some embodiments, the metal fill layer comprises tungsten, aluminum, copper, cobalt, and/or other suitable materials. In some embodiments, the first contact 51 comprises a metal silicide. Other structures and/or configurations of the first contact 51 are within the scope of the present disclosure.

In some embodiments, a first semiconductor material layer 102 is disposed between the first conductive structure 21 and the first semiconductor device 40a. In some embodiments, the first semiconductor material layer 102 separates the first conductive structure 21 from the first semiconductor device 40a in the horizontal directions (i.e., the first direction X and a second direction Y shown in FIGS. 2 and 3) and the vertical direction (i.e., a third direction Z shown in FIGS. 2 and 3). The first conductive structure 21 surrounds the first semiconductor material layer 102 from the plan view, and the first semiconductor material layer 102 surrounds at least a portion of the first semiconductor device 40a in the plan view. In some embodiments, the first semiconductor material layer 102 encircles the entire first semiconductor device 40a, as shown in FIG. 2.

In some embodiments, the first semiconductor material layer 102 is disposed on the first conductive structure 21, and is electrically connected to the first conductive structure 21. In some embodiments, the first conductive structure 21 is configured to transmit the uniform signal to the first semiconductor material layer 102. In some embodiments, sidewalls and a bottom of the first semiconductor material layer 102 are conformal to the first conductive structure 21. In some embodiments, the first semiconductor material layer 102 surrounds the first semiconductor device 40a. As shown in FIG. 1, the first semiconductor material layer 102 has a rectangular shape from the plan view. It should be understood that such shape is not intended to be limiting, and the first semiconductor material layer 102 may have other shapes in other embodiments. In some embodiments, the first semiconductor material layer 102 includes a single crystalline semiconductor material such as, but not limited to, at least one of Si, Ge, SiGe, InGaAs, GaAs, InSb, GaP, GaSb, InAlAs, GaSbP, GaAsSb, and InP.

In some embodiments, the first semiconductor material layer 102 and the substrate 101 include a same semiconductor material. In some embodiments, the first semiconductor material layer 102 and the substrate 101 include different semiconductor materials. In some embodiments, the substrate 101 and the first semiconductor material layer 102 have different conductivity types, wherein the substrate 101 has a first doping type, and the first semiconductor material layer 102 has a second doping type opposite to the first doping type. In some embodiments, the substrate 101 includes a p-type dopant, such as at least one of boron, BF₂, aluminum, gallium, indium, and other suitable p-type dopants. In some embodiments, the first semiconductor material layer 102 includes an n-type dopant, such as at least one of phosphorous, arsenic, and other suitable n-type dopants. In some embodiments, the first semiconductor material layer 102 serves as a doped well having the second doping type, such as an n-type well.

In some alternative embodiments, the substrate 101 and the first semiconductor material layer 102 have the same conductivity type. In some embodiments, both the substrate 101 and the first semiconductor material layer 102 have the first doping type.

In some embodiments, referring to FIGS. 2 and 3, a first isolation layer 31 is disposed under the first conductive structure 21. In some embodiments, when the substrate 101 and the first semiconductor material layer 102 have different conductivity types, the first isolation layer 31 is configured to isolate the electrical potential of the first semiconductor material layer 102 from the substrate 101. The first isolation layer 31 may be omitted when the substrate 101 and the first semiconductor material layer 102 have the same conductivity type.

In some embodiments, the first isolation layer 31 is disposed between the first conductive structure 21 and the substrate 101, such that the first conductive structure 21 is electrically isolated from the substrate 101 by the first isolation layer 31. The first isolation layer 31 includes a dielectric material such as oxide or the like. In some embodiments, the first isolation layer 31 includes silicon dioxide or the like. In some embodiments, the first isolation layer 31 includes a high-k (high dielectric constant) dielectric material, such as hafnium aluminum oxide (HfAlO), zirconium dioxide (ZrO₂), aluminum oxide, titanium oxide, or the like.

In some embodiments, a first doped layer 32 is disposed over the first conductive structure 21 and between the first conductive structure 21 and the first semiconductor material layer 102. The first conductive structure 21 is disposed between the first isolation layer 31 and the first doped layer 32. In some embodiments, the first semiconductor material layer 102 is disposed on the first doped layer 32 (as shown in FIG. 2) or between the first conductive structure 21 and the first semiconductor device 40a (as shown in FIG. 3). In some embodiments, the first semiconductor material layer 102 is electrically connected to the first conductive structure 21, and the first doped layer 32 can be omitted as shown in FIG. 3.

In some embodiments, the first conductive structure 21 is electrically connected to the first doped layer 32. In some embodiments, the first semiconductor material layer 102 and the first doped layer 32 have the same conductivity type, and therefore the first semiconductor material layer 102, the first doped layer 32 and the first conductive structure 21 are electrically connected. In some embodiments, the first semiconductor material layer 102 and the first doped layer 32 have the second doping type (n-type). In some embodiments, a dopant concentration of the first doped layer 32 is greater than a dopant concentration of the first semiconductor material layer 102, a resistance concentration of the first doped layer 32 is lower than a resistance concentration of the first semiconductor material layer 102, and the signal can therefore be more effectively transmitted to the first conductive structure 21 through the first doped layer 32. In some embodiments, the sidewalls and the bottom of the first semiconductor material layer 102 are conformal to the first doped layer 32.

The first doped layer 32 is disposed over the first conductive structure 21. In some embodiments, the first doped layer 32 entirely covers and is in contact with the first bottom portion 21a and the first sidewall portion 21b of the first conductive structure 21. The first doped layer 32 is conformal to the first conductive structure 21. The first doped layer 32 is enclosed by the oxide layer 41 and the first conductive structure 21. In some embodiments, a peripheral portion of the first doped layer 32 is coplanar with the first surface 101a of the substrate 101.

In some embodiments, a first isolation structure 35 may be disposed under the oxide layer 41 and may be formed adjacent to the first sidewall portion 21b of the first conductive structure 21 to provide electrical isolation for the first semiconductor device 40a from other elements or devices. The first upper portion 21c is disposed adjacent to the first semiconductor device 40a in the first direction X, and the first conductive structure 21 and the first semiconductor device 40a are separated by the first isolation structure 35. In some embodiments, the first isolation structure 35 is disposed between the first semiconductor device 40a and the first conductive structure 21. The first isolation structure 35 and the first conductive structure 21 are separated in the first direction X by a first distance D1. In one embodiment, the first distance D1 is greater than 5 μm. In some embodiments, the first isolation structure 35 is in contact with the first semiconductor device 40a or the first doped layer 32. In some embodiments, the first isolation structure 35 is a shallow trench isolation (STI). The first isolation structure 35 extends from the first surface 101a toward the second surface 101b of the substrate 101, and an upper surface of the first isolation structure 35 is coplanar with the first surface 101a. In some embodiments, a plurality of first isolation structures 35 are disposed between the first sidewall portion 21b and the first semiconductor device 40a. In some embodiments, the first isolation structure 35 includes an isolation material. In some embodiments, the first isolation structure 35 includes oxide or nitride.

In some embodiments, a second isolation structure 37 is disposed adjacent to the first conductive structure 21 to provide electrical isolation for the first conductive structure 21 from other elements or devices. In some embodiments, the first isolation layer 31 and the second isolation structure 37 provide electrical isolation for the first conductive structure 21 from the substrate 101. In some embodiments, the second isolation structure 37 surrounds at least a portion of the first conductive structure 21. The first upper portion 21c is disposed adjacent to the second isolation structure 37 in the first direction X, and the second isolation structure 37 and the first isolation structure 35 are separated by the first conductive structure 21. In some embodiments, the first upper portion 21c is disposed between the second isolation structure 37 and the first semiconductor material layer 102. In some embodiments, the first conductive structure 21 is surrounded by the isolation structure 37. In some embodiments, the second isolation structure 37 is an STI. The second isolation structure 37 extends from the first surface 101a toward the second surface 101b of the substrate 101. In some embodiments, the second isolation structure 37 is disposed under the oxide layer 41, and an upper surface of the second isolation structure 37 is coplanar with the first surface 101a. In some embodiments, a plurality of second isolation structures 37 surround the plurality of first isolation structures 35. In some embodiments, the second isolation structure 37 includes an isolation material. In some embodiments, the second isolation structure 37 includes oxide or nitride. In some embodiments, the first isolation structure 35 and the second isolation structure 37 include a same material.

The first semiconductor device 40a is fabricated in and/or on the first semiconductor material layer 102 in a region encircled by the first sidewall portion 21b of the first conductive structure 21. The first semiconductor device 40a is disposed over and separated from the first conductive structure 21. In some embodiments, the first semiconductor device 40a is disposed over the first doped layer 32. It should be noted that, in some embodiments, the first semiconductor device 40a includes the first isolation structure 35 as shown in FIG. 3; however, in other embodiments, the first semiconductor device 40a may include components of a transistor, a photodetector, an insulated-gate bipolar transistor (IGBT), a MOS device, a FET such as a MOSFET, a capacitance device, various combinations thereof, and/or the like.

Referring to FIG. 3, the first semiconductor device 40a includes a complementary metal oxide semiconductor (CMOS) device. In some embodiments, the CMOS device includes a p-type MOS (PMOS) device 42 and an n-type MOS (NMOS) device 43. A bottom surface of the first semiconductor device 40a may be at a vertical level lower than a vertical level of a bottom surface of the first isolation structure 35.

The PMOS device 42 includes an n-well region 421 under and between one of the first isolation structures 35 and an STI structure 39, p-type source/drain regions 422 in the n-well region 421, and a gate structure 423 over the n-well region 421. The NMOS device 43 is disposed adjacent to the PMOS device 42 and includes a p-well region 431 under and between one of the first isolation structures 35 and the STI structure 39, n-type source/drain regions 432 in the p-well region 431, and a gate structure 433 over the p-well region 431. In some embodiments, the oxide layer 41 serves as a gate dielectric layer between the gate structure 423 and the substrate 101, and as a gate dielectric layer between the gate structure 433 and the substrate 101. Other structures and configurations of the first semiconductor device 40a, the PMOS device 42, and/or the NMOS device 43 are within the scope of the present disclosure. In some embodiments, the oxide layer 41 serves as a gate oxide of the first semiconductor device 40a. In some embodiments, the oxide layer 41 covers the first semiconductor device 40a, the first surface 101a, the first doped layer 32, the first semiconductor material layer 102, and the first conductive structure 21.

Additionally, an inter-layer dielectric (ILD) may be formed to cover the first semiconductor device 40a (i.e., the PMOS device 42 and the NMOS device 43), though not shown in FIG. 3.

In some embodiments, referring to FIGS. 1, 2 and 3, the semiconductor structure 100b is disposed adjacent to the semiconductor structure 100a, and one of the second isolation structures 37 is disposed between the semiconductor structure 100a and the semiconductor structure 100b. In some embodiments, the semiconductor structure 100b includes a second conductive structure 22 of the conductive structure 20 and a second semiconductor material layer 103 disposed within the substrate and surrounded by the second conductive structure 22. The second conductive structure 22 is configured to transmit an uniform signal to the second semiconductor material layer 103. The second conductive structure 22 is electrically connected or electrically coupled to the second semiconductor material layer 103.

The second conductive structure 22 is disposed within the substrate 101 and adjacent to the first conductive structure 21. In some embodiments, the second conductive structure 22 is electrically isolated from the first conductive structure 21. In some embodiments, the second conductive structure 22 is surrounded by the isolation structure 37. The second conductive structure 22 includes a second bottom portion 22a and a second sidewall portion 22b disposed over and coupled to the second bottom portion 22a. In some embodiments, the second bottom portion 22a extends along the first direction X parallel to the first surface 101a. The second bottom portion 22a extends in the horizontal plane (i.e., the X-Y plane as shown in FIG. 1). The second bottom portion 22a is disposed under the second semiconductor material layer 103. In some embodiments, the second conductive structure 22 has a rectangular shape. Although the second conductive structure 22 of the semiconductor structure 100b is shown as being rectangular in FIG. 1, in other embodiments the second conductive structure 22 can comprise other shapes, such as hexagon, octagon, circle, or others. In some embodiments, the second bottom portion 22a has a shape conformal to the shape of the second conductive structure 22. In some embodiments, the second sidewall portion 22b encircles the second bottom portion 22a.

The second sidewall portion 22b extends upward from a perimeter of the second bottom portion 22a and toward the first surface 101a of the semiconductor substrate 101. In some embodiments, the second sidewall portion 22b reaches the first surface 101a of the semiconductor substrate 101. In some embodiments, the second sidewall portion 22b extends upward from two opposite sides of the second bottom portion 22a. In some embodiments, the second sidewall portion 22b extends upward from an entirety of the perimeter of the second bottom portion 22a. The second sidewall portion 22b is oriented at a second angle α2 respective to the plane of the second bottom portion 22a, as shown in FIGS. 2 and 3. In some embodiments, the second angle α2 between the second bottom portion 22a and the second sidewall portion 22b is close to 90°. In some embodiments, the second sidewall portion 22b is at an obtuse angle respective to the second bottom portion 22a. An acute angle is also contemplated for the second angle α2. In some embodiments, the second sidewall portion 22b is at an angle of between 85° and 160° respective to the plane of the second bottom portion 22a. It should also be noted that the second sidewall portion 22b may not be perfectly straight, e.g., the second sidewall portion 22b may have some curvature (not shown). Likewise, while the second bottom portion 22a is illustrated as being planar, some curvature to the second bottom portion 22a may also be present in some embodiments. The first angle α1 and the second angle α2 can be same or different.

In some embodiments, a second distance D2 between the first bottom portion 21a and the first surface 101a is similar to a third distance D3 between the second bottom portion 22a and the first surface 101a. In some embodiments, the second distance D2 is different from the third distance D3 according to particular requirements.

In some embodiments, the second conductive structure 22 further includes a second upper portion 22c coupled to the second sidewall portion 22b. The second sidewall portion 22b is disposed between the second bottom portion 22a and the second upper portion 22c, and the second upper portion 22c is in contact with a dielectric layer, such as the oxide layer 41. In some embodiments, the second upper portion 22c extends from the second sidewall portion 22b and away from the second bottom portion 22a along the first direction X. In some embodiments, a top surface of the second upper portion 22c is coplanar with the first surface 101a. In some embodiments, the second upper portion 22c encircles the second bottom portion 22a in a plan view. In some embodiments, the second conductive structure 22 is integral and continuous. In some embodiments, the second bottom portion 22a, the second sidewall portion 22b and the second upper portion 22c are integral and continuous. In some embodiments, the second conductive structure 22 includes segments.

In some embodiments, the second conductive structure 22 includes several conductive layers. In some embodiments, a periphery of the second conductive structure 22 is isolated from the substrate 101. The second conductive structure 22 may include a conductive material such as copper, titanium nitride (TiN), metal silicide, polysilicon, or the like. In some embodiments, the second conductive structure 22 includes nickel silicide or cobalt silicide.

The second conductive structure 22 is electrically coupled to a second contact 52 disposed over the second conductive structure 22. In some embodiments, the second contact 52 is disposed over the second upper portion 22c of the second conductive structure 22, and the second contact 52 extends through at least the oxide layer 41. In some embodiments, the second bottom portion 22a is surrounded by a plurality of the second contacts 52. In some embodiments, the second contact 52 comprises a barrier layer, a seed layer, a metal fill layer, and/or other suitable layers. In some embodiments, the second contact 52 comprises a metal silicide. Configurations and compositions of the first contact 51 and the second contact 52 can be same or different.

In some embodiments, the second semiconductor material layer 103 is surrounded by the second conductive structure 22 in the plan view. In some embodiments, the second conductive structure 22 encircles the second semiconductor material layer 103 in the plan view.

In some embodiments, the second semiconductor material layer 103 is disposed on the second conductive structure 22, and is electrically connected to the second conductive structure 22. In some embodiments, sidewalls and a bottom of the second semiconductor material layer 103 are conformal to the second conductive structure 22. As shown in FIG. 1, the second semiconductor material layer 103 has a rectangular shape in the plan view. It should be understood that such shape is not intended to be limiting, and the second semiconductor material layer 103 may have other shapes in other embodiments. In some embodiments, the second semiconductor material layer 103 includes a single crystalline semiconductor material such as, but not limited to, at least one of Si, Ge, SiGe, InGaAs, GaAs, InSb, GaP, GaSb, InAlAs, GaSbP, GaAsSb, and InP.

In some embodiments, the second semiconductor material layer 103 and the substrate 101 include a same semiconductor material. In some embodiments, the second semiconductor material layer 103 and the substrate 101 include different semiconductor materials.

In some alternative embodiments, the substrate 101 and the second semiconductor material layer 103 have a same conductivity type. In some embodiments, the substrate 101 and the second semiconductor material layer 103 have the first doping type. In some embodiments, both of the substrate 101 and the second semiconductor material layer 103 include the p-type dopant. In some embodiments, the second semiconductor material layer 103 serves as a doped well having the first doping type, such as a p-type well.

In some embodiments, the substrate 101 and the second semiconductor material layer 103 have different conductivity types, such as the substrate 101 having the first doping type and the second semiconductor material layer 103 having the second doping type. In some embodiments, the substrate 101 includes the p-type dopant, and the second semiconductor material layer 103 includes the n-type dopant.

In some embodiments, referring to FIGS. 2 and 3, a second isolation layer 33 is disposed under the second conductive structure 22 and configured to electrically isolate the second conductive structure 22 from the substrate 101, wherein the second semiconductor material layer 103 and the substrate 101 may have same or different electrical potentials. The second isolation layer 33 may be omitted when the substrate 101 and the second semiconductor material layer 103 have a same conductivity type; in such embodiments, the second conductive structure 22 is in contact with the substrate 101, and the second semiconductor material layer 103 and the substrate 101 may have the same electrical potentials.

In some embodiments, the second isolation layer 33 is disposed between the second conductive structure 22 and the substrate 101. The second isolation layer 33 includes a dielectric material such as oxide or the like. In some embodiments, the second isolation layer 33 includes silicon dioxide or the like. In some embodiments, the second isolation layer 33 includes a high-k dielectric material, such as hafnium aluminum oxide (HfAlO), zirconium dioxide (ZrO₂), aluminum oxide, titanium oxide, or the like.

In some embodiments, a second doped layer 34 is disposed over the second conductive structure 22 and between the second conductive structure 22 and the second semiconductor material layer 103. In some embodiments, the second conductive structure 22 is disposed between the second isolation layer 33 and the second doped layer 34 as shown in FIG. 2. In some embodiments, the second conductive structure 22 is disposed between and electrically connected to the substrate 101 and the second semiconductor material layer 103, and the second doped layer 34 can be omitted as shown in FIG. 3.

In some embodiments, the second semiconductor material layer 103 and the second doped layer 34 have a same conductivity type, and the second semiconductor material layer 103, the second doped layer 34 and the second conductive structure 22 are electrically connected. In some embodiments, the substrate 101, the second semiconductor material layer 103 and the second doped layer 34 have the first doping type (p-type). In some embodiments, a dopant concentration of the second doped layer 34 is greater than a dopant concentration of the second semiconductor material layer 103, and a resistance concentration of the second doped layer 34 is lower than a resistance concentration of the second semiconductor material layer 103. In some embodiments, the sidewalls and the bottom of the second semiconductor material layer 103 are conformal to the second doped layer 34.

The second doped layer 34 is disposed over the second conductive structure 22. In some embodiments, the second doped layer 34 entirely covers and is in contact with the second bottom portion 22a and the second sidewall portion 22b of the second conductive structure 22, such that the second conductive structure 22 is electrically connected to the second doped layer 34. The second doped layer 34 is conformal to the second conductive structure 22. The second doped layer 34 is enclosed by the oxide layer 41 and the second conductive structure 22. In some embodiments, a peripheral portion of the second doped layer 34 is coplanar with the first surface 101a of the substrate 101.

In some embodiments, the first isolation structure 35 may be formed adjacent to the second sidewall portion 22b of the second conductive structure 22 to provide electrical isolation for the second conductive structure 22 from other elements or devices. The second upper portion 22c is disposed adjacent to the first isolation structure 35. In some embodiments, the first isolation structure 35 is surrounded by the second conductive structure 22. The first isolation structure 35 and the second conductive structure 22 are separated in the first direction X by a portion of the second semiconductor material layer 103. In some embodiments, the first isolation structure 35 is in contact with the second semiconductor material layer 103 and/or the second doped layer 34. In some embodiments, a plurality of the first isolation structures 35 are disposed adjacent to the second sidewall portion 22b and the first sidewall portion 21b.

In some embodiments, the second isolation structure 37 is disposed adjacent to the second conductive structure 22 to provide electrical isolation for the second conductive structure 22 from the substrate 101. In some embodiments, the plurality of second isolation structures 37 surround at least a portion of the second conductive structure 22. The second upper portion 22c is disposed adjacent to the second isolation structure 37 in the first direction X, and the second isolation structure 37 and the first isolation structure 35 are separated by the second conductive structure 22. In some embodiments, the second upper portion 22c is disposed between the second isolation structure 37 and the second semiconductor material layer 103.

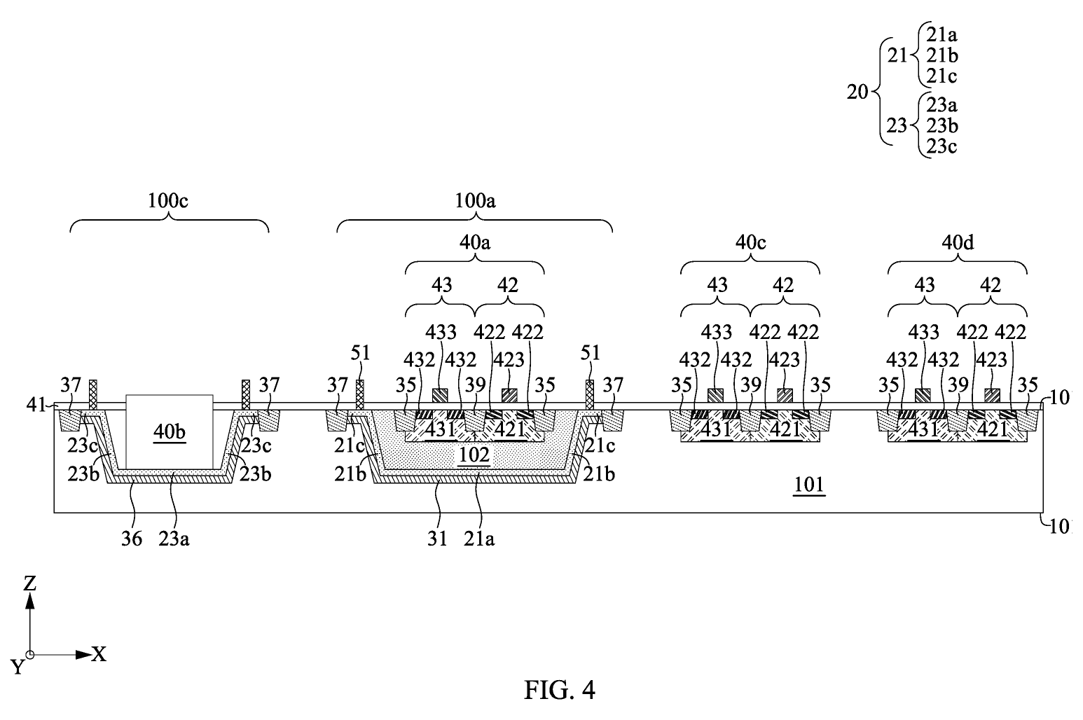

FIG. 4 is a schematic cross-sectional view of a semiconductor structure according to aspects of the present disclosure in some embodiments. A plurality of semiconductor structures 100a and 100c are disposed on a first surface 101a of a substrate 101, wherein the semiconductor structure 100a includes a first semiconductor device 40a. The semiconductor structure 100a and the first semiconductor device 40a illustrated in FIG. 4 are similar to the semiconductor structure 100a and the first semiconductor device 40a illustrated in FIGS. 1, 2 and 3. However, the semiconductor structure 100c shown in FIG. 4 includes a second semiconductor device 40b. In some embodiments, semiconductor devices 40c and 40d are disposed adjacent to the semiconductor structure 100a. In some embodiments, the semiconductor devices 40c and 40d are embedded in and surrounded by the substrate 101. The semiconductor devices 40c and 40d can be similar to or different form the first semiconductor devices 40a. In some embodiments, each of the semiconductor devices 40c and 40d includes a CMOS device.

The second semiconductor device 40b of the semiconductor structure 100c is disposed on a third conductive structure 23. A configuration of the third conductive structure 23 may be similar to that of the first conductive structure 21. In some embodiments, the third conductive structure 23 is disposed within the substrate 101 and includes a third bottom portion 23a and a third sidewall portion 23b disposed over and coupled to the third bottom portion 23a, and further includes a third upper portion 23c coupled to the third sidewall portion 23b. In some embodiments, the second semiconductor device 40b is surrounded by the substrate 101. In some embodiments, the third conductive structure 23 is partially enclosed by the oxide layer 41 and a third isolation layer 36. The third conductive structure 23 is conformal with the third isolation layer 36.

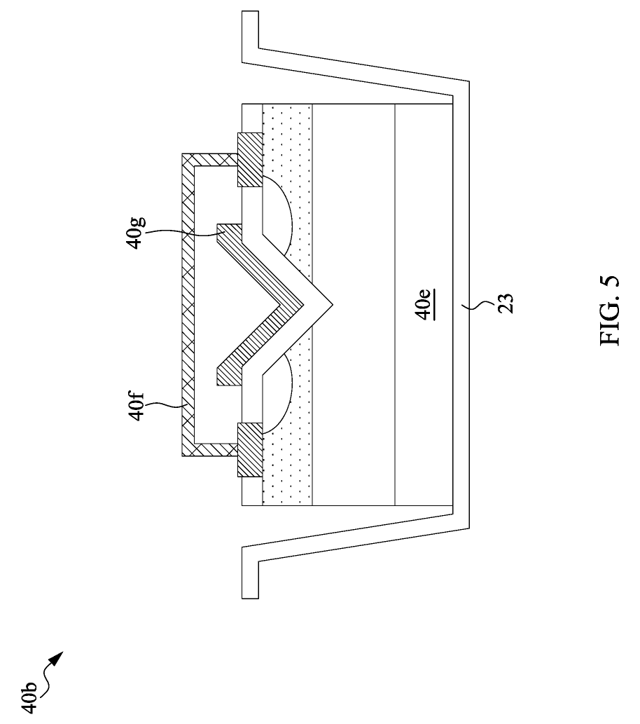

FIGS. 5, 6 and 7 are schematic cross-sectional views of a second semiconductor device 40b and a third conductive structure 23 according to aspects of the present disclosure in some embodiments. In some embodiments, referring to FIG. 5, the second semiconductor device 40b includes a V-shaped MOS (VMOS). The second semiconductor device 40b is electrically coupled to the third conductive structure 23. In some embodiments, the second semiconductor device 40b includes a drain electrode 40e disposed at a bottom of the second semiconductor device 40b, wherein the drain electrode 40e is electrically coupled to a third bottom portion 23a of the third conductive structure 23. In some embodiments, the second semiconductor device 40b includes a source electrode 40f disposed at a top of the second semiconductor device 40b, and a gate electrode 40g having a V-shape gate material.

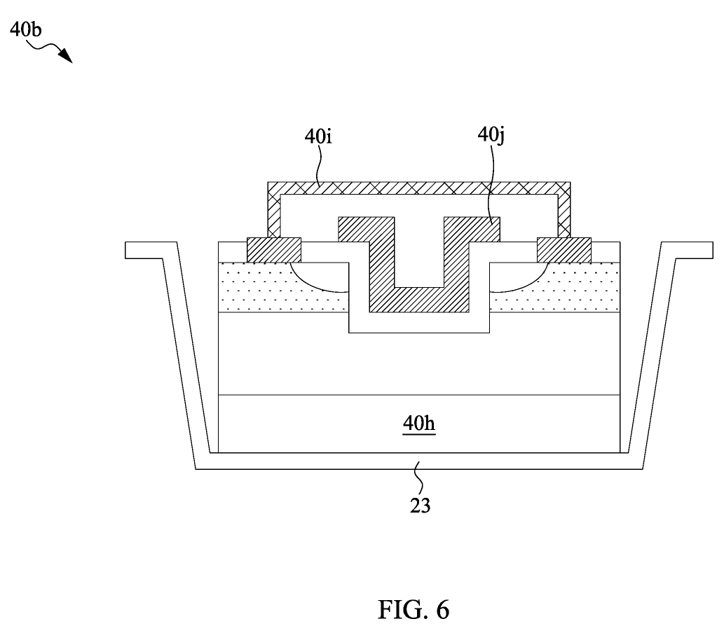

In some embodiments, referring to FIG. 6, the second semiconductor device 40b includes a U-shaped MOS (UMOS). The second semiconductor device 40b is electrically coupled to the third conductive structure 23 through a drain electrode 40h disposed at a bottom of the second semiconductor device 40b, wherein the drain electrode 40h is electrically coupled to the third bottom portion 23a of the third conductive structure 23. In some embodiments, the second semiconductor device 40b includes a source electrode 40i disposed at a top of the second semiconductor device 40b and a gate electrode 40j having a U-shape gate material.

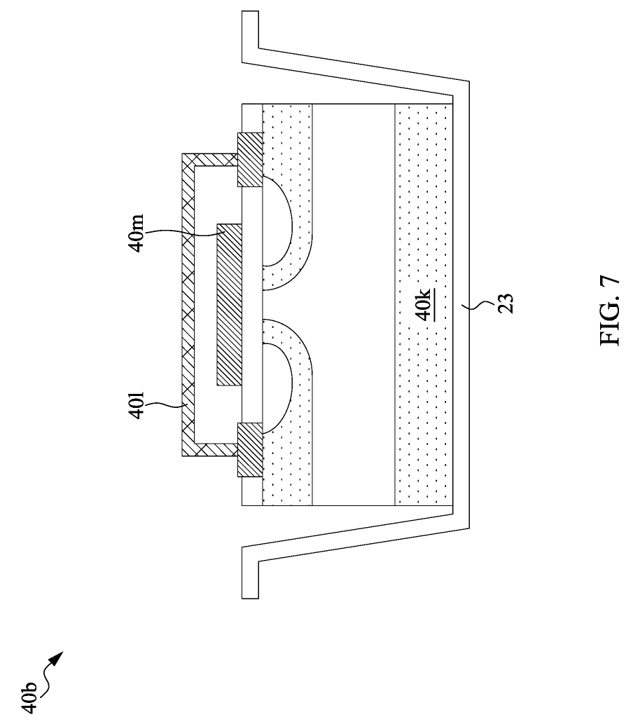

In some embodiments, referring to FIG. 7, the second semiconductor device 40b includes an insulated gate bipolar transistor (IGBT). The second semiconductor device 40b is electrically coupled to the third conductive structure 23 through a drain electrode (or a collector) 40k disposed at a bottom of the second semiconductor device 40b, wherein the drain electrode (or the collector) 40k is electrically coupled to the third bottom portion 23a of the third conductive structure 23. In some embodiments, the second semiconductor device 40b includes a source electrode (or an emitter) 40l disposed at a top of the second semiconductor devices 40b and a gate material 40m.

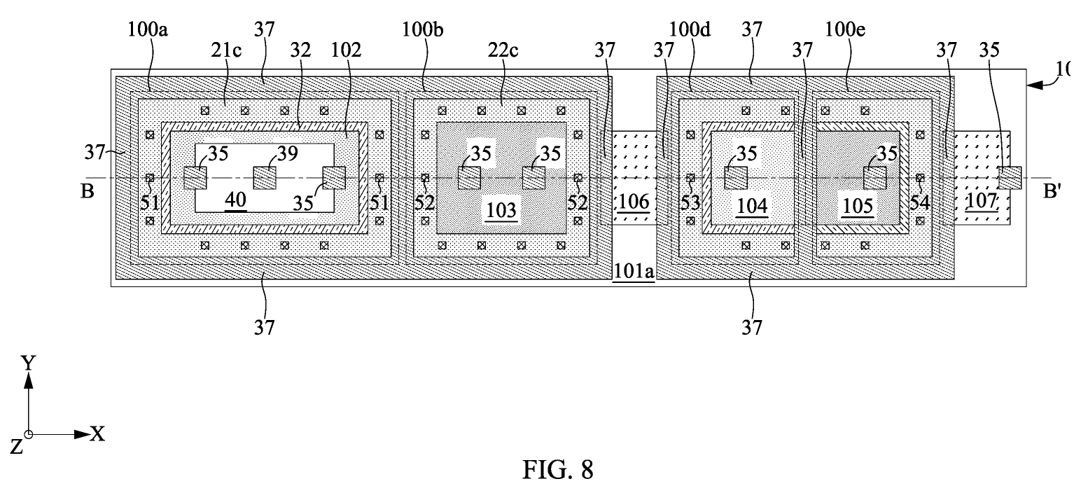

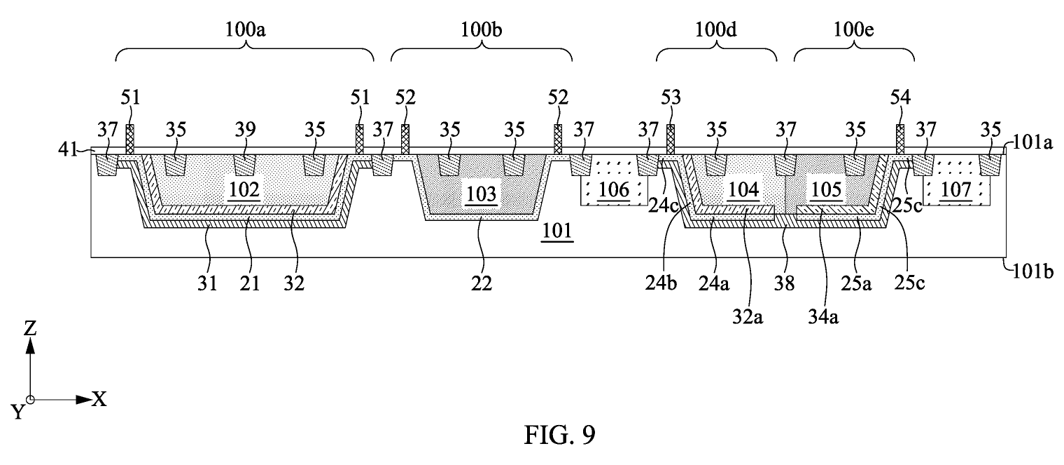

FIG. 8 is a schematic top view of a semiconductor structure according to aspects of the present disclosure in some embodiments. FIG. 9 is a schematic cross-sectional view taken along a line B-B' in FIG. 8. Referring to FIGS. 8 and 9, semiconductor structures 100a, 100b, 100d and 100e are disposed on a first surface 101a of a substrate 101.

The semiconductor structures 100a and 100b illustrated in FIGS. 8 and 9 are similar to the semiconductor structures 100a and 100b illustrated in FIGS. 1, 2 and 3. However, the semiconductor structures 100d and 100e shown in FIGS. 8 and 9 include a fourth conductive structure 24 and a fifth conductive structure 25. The semiconductor structure 100d is disposed adjacent to the semiconductor structure 100e. In some embodiments, the fourth conductive structure 24 includes a fourth bottom portion 24a.

In some embodiments, the fourth conductive structure 24 further includes a fourth sidewall portion 24b disposed over and coupled to the fourth bottom portion 24a, and a fourth upper portion 24c coupled to the fourth sidewall portion 24b and exposed through the first surface 101a. In some embodiments, the fifth conductive structure 25 further includes a fifth sidewall portion 25b disposed over and coupled to the fifth bottom portion 25a, and a fifth upper portion 25c coupled to the fifth sidewall portion 25b and exposed through the first surface 101a. The fourth semiconductor material layer 104 is in contact with the fifth semiconductor material layer 105.

In some embodiments, the fourth semiconductor material layer 104, the fourth bottom portion 24a, the fourth sidewall portion 24b, and the fourth upper portion 24c are part of the semiconductor structure 100d. In some embodiments, the fourth semiconductor material layer 104 has the second doping type (n-type) and is in contact with the fourth bottom portion 24a, the fourth sidewall portion 24b and the fourth upper portion 24c. In some embodiments, a third contact 53 is disposed on and electrically coupled to the fourth upper portion 24c.

In some embodiments, the fifth semiconductor material layer 105, the fifth bottom portion 25a, the fifth sidewall portion 25b, and the fifth upper portion 25c are part of the semiconductor structure 100e. In some embodiments, the fifth semiconductor material layer 105 has a first doping type (p-type) and is in contact with the fifth bottom portion 25a, the fifth sidewall portion 25b and the fifth upper portion 25c. In some embodiments, a fourth contact 54 is disposed on and electrically coupled to the fifth upper portion 25c. In some embodiments, the fourth bottom portion 24a, the fourth sidewall portion 24b, the fourth upper portion 24c, the fifth bottom portion 25a, the fifth sidewall portion 25b and the fifth upper portion 25c are formed simultaneously.

In some embodiments, a fourth isolation layer 38 is disposed under and conformal with the fourth conductive structure 24 and the fifth conductive structure 25. The fourth isolation layer 38 is disposed in the semiconductor structures 100d and 100e. At least a portion of the fourth isolation layer 38 is disposed between the fourth bottom portion 24a and the fifth bottom portion 25a. Thus the fourth contuctive structure 24 and the fifth conductive structure 25 are electrically isolated from each other by fourth isolation layer 38 and the second isolation structure 37.

In some embodiments, a fourth doped layer 32a is disposed over the fourth bottom portion 24a and the fourth sidewall portion 24b. In some embodiments, the fourth semiconductor material layer 104 is disposed on the fourth doped layer 32a and between the fourth doped layer 32a and the fifth semiconductor material layer 105.

In some embodiments, the fourth semiconductor material layer 104 and the fourth doped layer 32a have a same conductivity type, and the fourth semiconductor material layer 104 is therefore electrically connected to the fourth bottom portion 24a, the fourth sidewall portion 24b, the fourth upper portion 24c, and the fourth doped layer 32a. In some embodiments, the fourth doped layer 32a is omitted.

In some embodiments, the fourth semiconductor material layer 104 and the fourth doped layer 32a have the second doping type, such as n-type. In some embodiments, a dopant concentration of the fourth doped layer 32a is greater than a dopant concentration of the fourth semiconductor material layer 104. In some embodiments, sidewalls and a bottom of the fourth semiconductor material layer 104 are conformal to the fourth doped layer 32a.

In some embodiments, the fourth doped layer 32a entirely covers and is in contact with the fourth bottom portion 24a and the fourth sidewall portion 24b. The fourth doped layer 32a is partially enclosed by the oxide layer 41, the fourth bottom portion 24a and the fourth sidewall portion 24b. In some embodiments, a peripheral portion of the fourth doped layer 32a is coplanar with the first surface 101a of the substrate 101. In some embodiments, one of the first isolation structures 35 is surrounded by the fourth semiconductor material layer 104.

In some embodiments, a fifth doped layer 34a is disposed over the fifth bottom portion 25a and the fifth sidewall portion 25b. In some embodiments, the fifth semiconductor material layer 105 is disposed on the fifth doped layer 34a and between the fifth doped layer 34a and the fourth semiconductor material layer 104.

In some embodiments, the fifth semiconductor material layer 105 and the fifth doped layer 34a have a same conductivity type, and the fifth semiconductor material layer 105 is therefore electrically connected to the fifth bottom portion 25a, the fifth sidewall portion 25b, the fifth upper portion 25c and the fifth doped layer 34a. In some embodiments, the fifth doped layer 34a is omitted.

In some embodiments, the fifth semiconductor material layer 105 and the fifth doped layer 34a have the first doping type, such as p-type. In some embodiments, a dopant concentration of the fifth doped layer 34a is greater than a dopant concentration of the fifth semiconductor material layer 105. In some embodiments, sidewalls and a bottom of the fifth semiconductor material layer 105 are conformal to the fifth doped layer 34a.

In some embodiments, the fifth doped layer 34a entirely covers and is in contact with the fifth bottom portion 25a and the fifth sidewall portion 25b. The fifth doped layer 34a is partially enclosed by the oxide layer 41, the fifth bottom portion 25a, and the fifth sidewall portion 25b. In some embodiments, a peripheral portion of the fifth doped layer 34a is coplanar with the first surface 101a of the substrate 101. In some embodiments, the first isolation structure 35 is surrounded by the fifth semiconductor material layer 105.

In some embodiments, a sixth semiconductor material layer 106 is disposed between and electrically isolated from the semiconductor structure 100a and the semiconductor structure 100d. In some embodiments, the sixth semiconductor material layer 106 has the second doping type, such as n-type.

In some embodiments, a seventh semiconductor material layer 107 is disposed adjacent to and electrically isolated from the semiconductor structure 100e. In some embodiments, the semiconductor structures 100d and 100e are disposed between the sixth semiconductor material layer 106 and the seventh semiconductor material layer 107. In some embodiments, the seventh semiconductor material layer 107 has the first doping type, such as p-type.

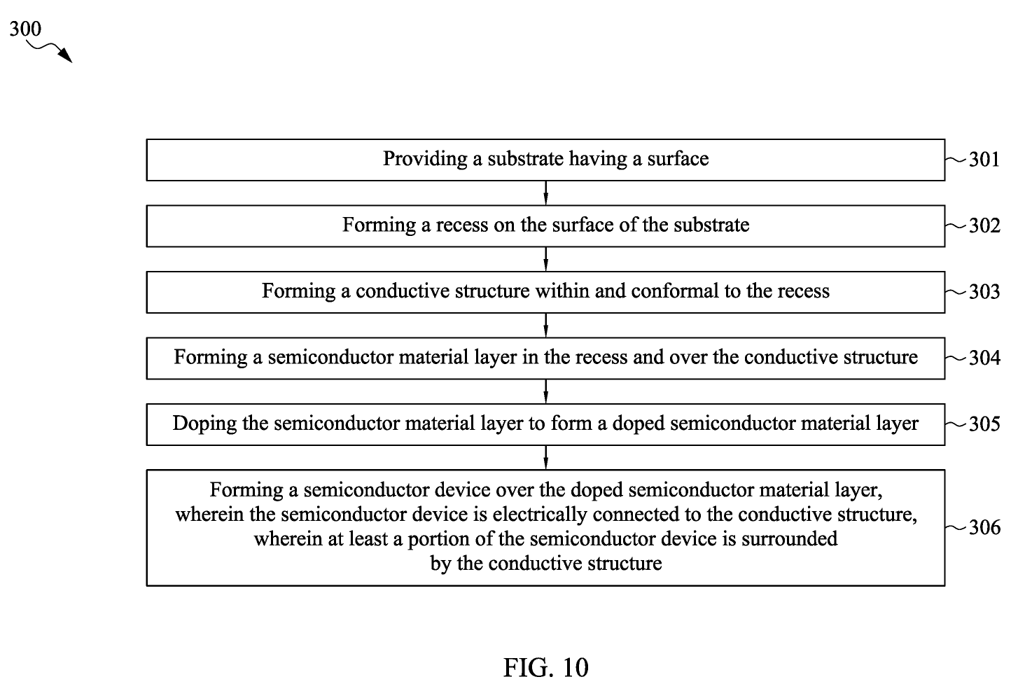

In accordance with some embodiments of the present disclosure, a method for manufacturing a semiconductor structure is disclosed. In some embodiments, the semiconductor structure 100a is fabricated by the method 300. FIG. 10 is a flowchart of the method 300 in accordance with some embodiments. The method 300 includes a number of operations (301 to 306), and descriptions and illustrations are not deemed as a limitation to a sequence of the operations. Additional steps can be provided before, during, and after the operations shown in FIG. 10, and some of the operations described below can be replaced or eliminated in other embodiments of the method 300. An order of the operations may be interchangeable.

Operation 301 includes providing a substrate having a surface. Operation 302 includes forming a recess on the surface of the substrate. Operation 303 includes forming a conductive structure within and conformal to the recess. Operation 304 includes forming a semiconductor material layer in the recess and over the conductive structure. Operation 305 includes doping the semiconductor material layer to form a doped semiconductor material layer. Operation 306 includes forming a semiconductor device over the doped semiconductor material layer, wherein the semiconductor device is electrically connected to the conductive structure and at least a portion of the semiconductor device is surrounded by the conductive structure.

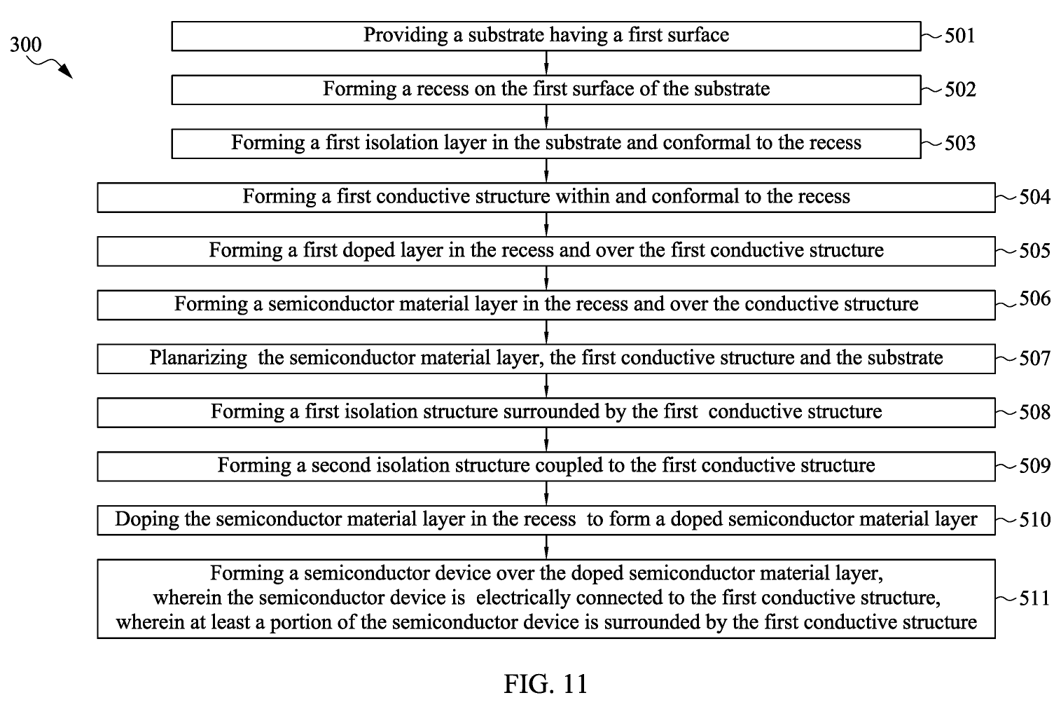

In accordance with some embodiments of the present disclosure, a method for manufacturing a semiconductor structure is disclosed. In some embodiments, the semiconductor structure 100a is fabricated by the method 500. FIG. 11 is a flowchart of the method 500 in accordance with some embodiments. The method 500 includes a number of operations (501 to 511), and descriptions and illustrations are not deemed as a limitation to a sequence of the operations. Additional steps can be provided before, during, and after the operations shown in FIG. 11, and some of the operations described below can be replaced or eliminated in other embodiments of the method 500. An order of the operations may be interchangeable.

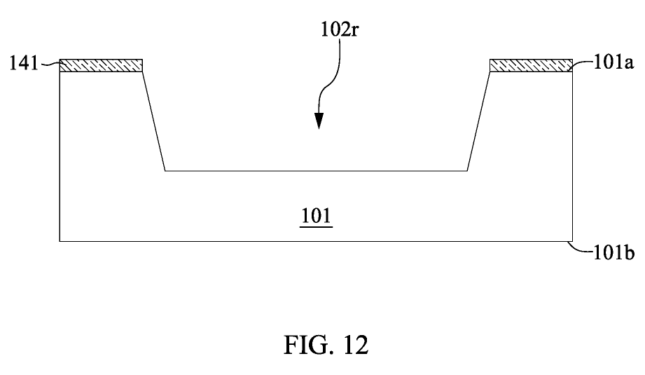

FIGS. 12 to 24 are schematic cross-sectional views of one or more operations of the method 500 for manufacturing a semiconductor structure in accordance with some embodiments of the present disclosure. The method 500 begins with operation 501. Operation 501 includes providing or receiving a substrate 101 having a first surface 101a and a second surface 101b opposite to the first surface 101a. The method 500 continues with operation 502. Operation 502 includes forming a recess 102r in the first surface 101a of the substrate 101. In some embodiments, operation 501 and operation 502 of the method 500 are similar to operation 301 and operation 302 of the method 300.

Referring to FIG. 12, in accordance with some embodiments, a mask layer 141 is formed over the first surface 101a of the substrate 101, and the recess 102r is formed in the substrate 101 using the mask layer 141 as a removal template. In some embodiments, the recess 102r is U-shaped.

In some embodiments, the mask layer 141 is a hard mask layer. The hard mask layer is formed by at least one of physical vapor deposition (PVD) (e.g., sputtering and/or evaporation), chemical vapor deposition (CVD) (e.g., low pressure CVD (LPCVD), ultrahigh vacuum CVD (UHVCVD), reduced pressure CVD (RPCVD), plasma-enhanced CVD (PECVD), and/or atmospheric pressure CVD (APCVD)), spin coating, growth, and other suitable techniques. In some embodiments, the hard mask layer comprises at least one of silicon and oxygen, silicon and nitrogen, nitrogen, silicon (e.g., polycrystalline silicon), and other suitable materials.

In some embodiments, the recess 102r is formed in the substrate 101 by performing an etching process to remove portions of the substrate 101 exposed by the mask layer 141. The substrate 101 is etched from the first surface 101a toward the second surface 101b to form the recess 102r. The etching process comprises at least one of a plasma etching process, a reactive ion etching (RIE) process, and other suitable techniques. Other structures and configurations of the recess 102r are within the scope of the present disclosure.

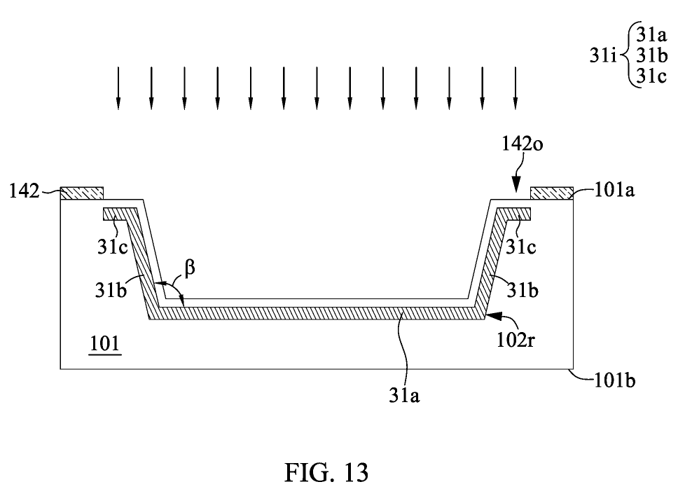

The method 500 continues with operation 503. Operation 503 includes forming a first implanted region 31i in the substrate 101, wherein the first implanted region 31i is conformal to the recess 102r. In some embodiments, referring to FIG. 13, the mask layer 141 is removed. The mask layer 141 is stripped or washed away before the first implanted region 31i is formed. In some embodiments, a mask layer 142 having an opening 142o is formed over the first surface 101a of the substrate 101.

In some embodiments, a bottom and a sidewall of the recess 102r are treated with an ion implant to form a dielectric material. In some embodiments, an implantation process is performed to implant oxygen, nitrogen, carbon, or similar ions into the substrate 101 along the bottom and the sidewall of the recess 102r, forming the first implanted region 31i. The first implanted region 31i includes a bottom portion 31a, a sidewall portion 31b and an upper portion 31c extending from the sidewall portion 31b and away from the bottom portion 31a. In some embodiments, an angle β between the bottom portion 31a and the sidewall portion 31b is greater than 90°.

In some embodiments, the first implanted region 31i includes oxygen ions. A depth of the first implanted region 31i is determined by a level of energy used to perform the implantation process. For example, in an embodiment, oxygen ions are implanted at a dose of about 5e14 to about 5e18 atoms/cm² and at an energy of about 100KeV to about 500 KeV.

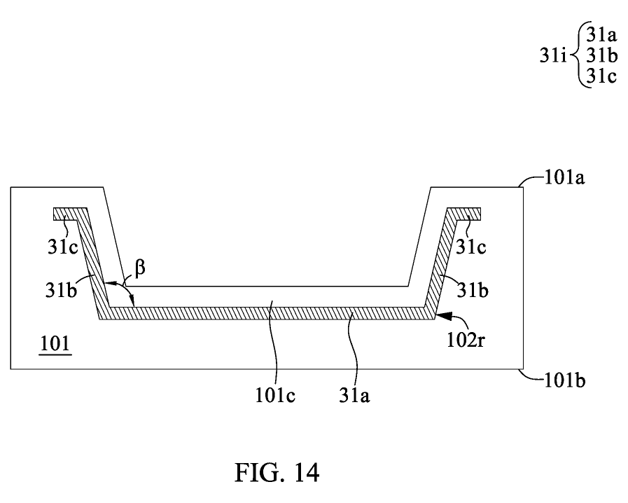

In some embodiments, referring to FIG. 14, the mask layer 142 is removed. The mask layer 142 is stripped or washed away after the first implanted region 31i is formed. In some embodiments, an epitaxial growth process is performed to form an epitaxy (or epi) semiconductor layer 101c after the implantation process. In some embodiments, the epitaxy semiconductor layer 101c includes silicon. In some embodiments, the epitaxy semiconductor layer 101c is formed on the bottom and the sidewall of the recess 102r and over the first surface 101a. In some embodiments, the epitaxy semiconductor layer 101c includes a material same as a material of the substrate 101 and redefines the first surface 101a of the substrate 101.

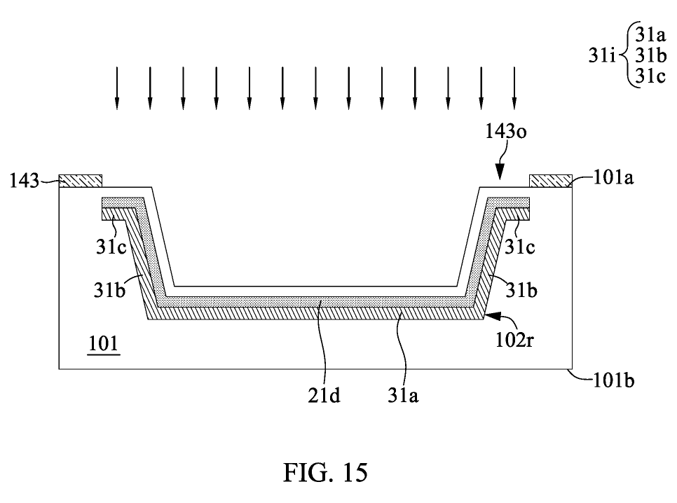

The method 500 continues with operation 504. Operation 504 includes forming a first conductive structure 21 within and conformal to the recess 102r. In some embodiments, operation 504 of the method 500 is similar to operation 303 of the method 300. In some embodiments, referring to FIG. 15, a mask layer 143 having an opening 143o is formed over the first surface 101a. In some embodiments, operation 504 includes forming a doped layer 21d in the recess 102r. In some embodiments, the doped layer 21d is conformal to the first implanted region 31i and is formed over the bottom portion 31a, the sidewall portion 31b and the upper portion 31c of the first implanted region 31i. The doped layer 21d covers an entirety of the first implanted region 31i.

In some embodiments, the doped layer 21d is formed by introducing an impurity into the epitaxy semiconductor layer 101c and/or the substrate 101. The impurity may be a p-type dopant, such as at least one of boron, BF₂, aluminum, gallium, indium, and other suitable p-type dopants. The impurity may be an n-type dopant, such as at least one of phosphorous, arsenic, and other suitable n-type dopants. In some embodiments, the doped layer 21d includes nickel ion. A depth of the doped layer 21d is determined by a level of energy used to introduce the impurity. For example, in an embodiment, nickel ions are implanted at a dose of about 10¹³ to about 10¹⁵ atoms/cm² and at an energy of about 200 KeV to about 600 KeV.

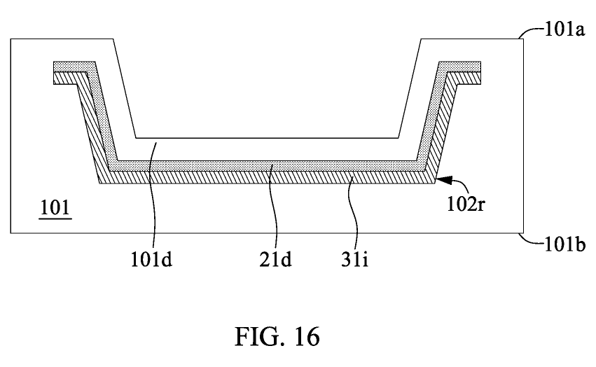

In some embodiments, referring to FIG. 16, the mask layer 143 is removed. The mask layer 143 is stripped or washed away after the doped layer 21d is formed. In some embodiments, an epitaxial growth process is performed to form an epitaxy (or epi) semiconductor layer 101d over the doped layer 21d. In some embodiments, the epitaxy semiconductor layer 101d is formed over the first surface 101a and the entire doped layer 21d. In some embodiments, the epitaxy semiconductor layer 101d includes silicon. In some embodiments, the epitaxy semiconductor layer 101d includes a material same as a material of the substrate 101 and redefines the first surface 101a of the substrate 101.

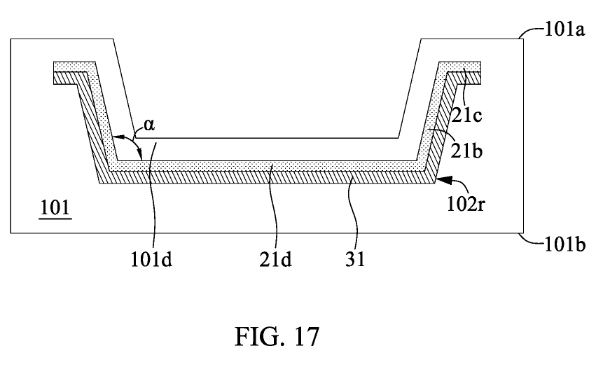

In some embodiments, referring to FIG. 17, operation 503 and operation 504 further include annealing the substrate 101 to transform the first implanted region 31i into a first isolation layer 31, and to transform the doped layer 21d into a first conductive structure 21. In some embodiments, the first conductive structure 21 includes metal silicide. In some embodiments, the first isolation layer 31 includes silicon dioxide. In some embodiments, the annealing is performed after the doped layer 21d is formed.

In some embodiments, the formation of the first conductive structure 21 includes forming a first bottom portion 21a within the recess 102r, forming a first sidewall portion 21b disposed over and coupled to the first bottom portion 21a within the recess 102r, and forming a first upper portion 21c coupled to and extending from the first sidewall portion 21b and away from the first bottom portion 21a. In some embodiments, the first bottom portion 21a, the first sidewall portion 21b and the first upper portion 21c are formed simultaneously. In some embodiments, an angle α formed between the first bottom portion 21a and the first sidewall portion 21b is greater than 90°. In some embodiments, the angle α is substantially identical to the angle β.

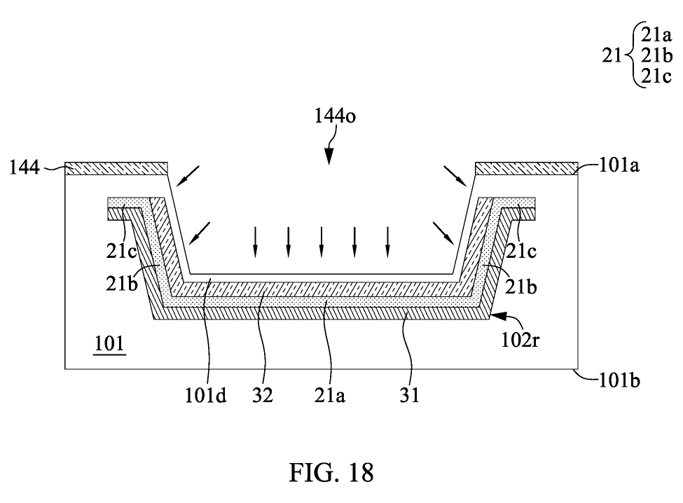

The method 500 continues with operation 505. Operation 505 includes forming a first doped layer 32 in the recess 102r and over the first conductive structure 21. In some embodiments, referring to FIG. 18, the first doped layer 32 is conformal to and formed over the first conductive structure 21. The first doped layer 32 covers an entirety of the first conductive structure 21. In some embodiments, a mask layer 144 having an opening 144o is formed over the first surface 101a of the substrate 101 during the formation of the first doped layer 32. The epitaxy semiconductor layer 101d is treated with an ion implant.

In some embodiments, the first doped layer 32 is formed by introducing an impurity into the epitaxy semiconductor layer 101d and/or the substrate 101. The impurity may be a p-type dopant, such as at least one of boron, BF₂, aluminum, gallium, indium, and other suitable p-type dopants. The impurity may be an n-type dopant, such as at least one of phosphorous, arsenic, and other suitable n-type dopants.

In some embodiments, the first doped layer 32 includes the n-type dopant. A depth of the first doped layer 32 is determined by a level of energy used to perform the implantation process. For example, in an embodiment, the n-type dopants are implanted at a dose of about 10¹⁴ to about 10¹⁶ atoms/cm² and at an energy of about 5 KeV to about 50 KeV.

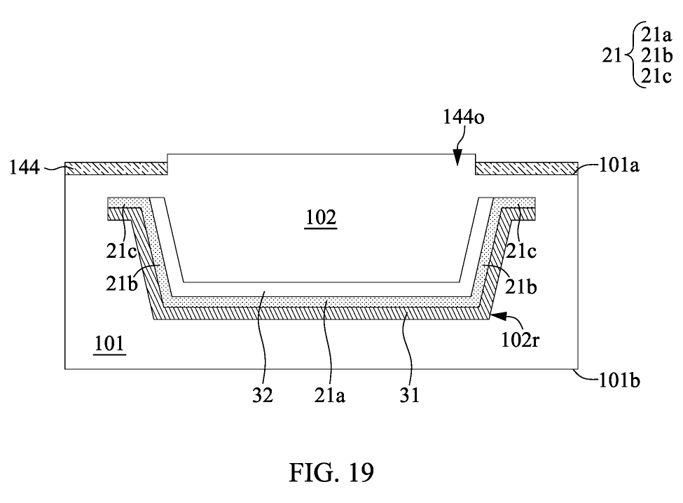

The method 500 continues with operation 506. Operation 506 includes forming a semiconductor material layer 102 in the recess 102r and over the first conductive structure 21. In some embodiments, operation 506 of the method 500 is similar to operation 304 of the method 300. In some embodiments, referring to FIG. 19, the semiconductor material layer 102 is formed in the recess 102r through the opening 144o. In some embodiments, the opening 144o and the recess 102r have the semiconductor material layer 102 formed therein, and the semiconductor material layer 102 is conformal to the recess 102r. In some embodiments, the semiconductor material layer 102 is formed over the first surface 101a of the substrate 101 and in the recess 102r. In some embodiments, the semiconductor material layer 102 is formed over the first doped layer 32. The semiconductor material layer 102 may be deposited by PVD, CVD, sputter deposition, or another technique for depositing the selected material.

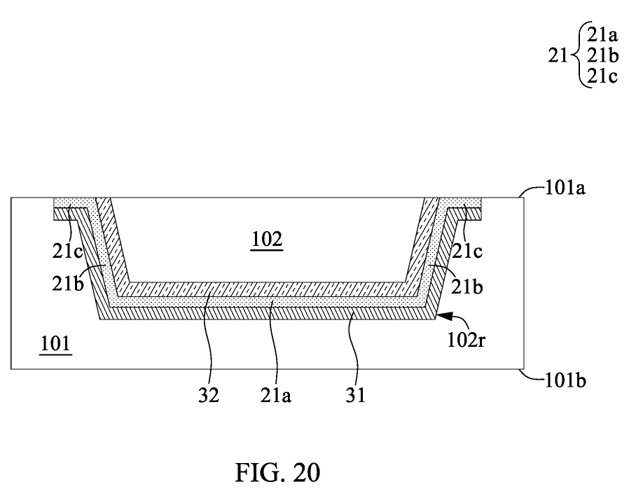

The method 500 continues with operation 507. Operation 507 includes planarizing the semiconductor material layer 102, the first conductive structure 21 and the substrate 101. In some embodiments, referring to FIG. 20, the mask layer 144 is removed. The mask layer 144 is stripped or washed away after the semiconductor material layer 102 is formed. In some embodiments, the semiconductor material layer 102 may be deposited over the surface 101a of the substrate 101 and then planarized, such as by a CMP processes or a mechanical grinding process. A planarization process is performed to align top surfaces of the semiconductor material layer 102, the substrate 101, the first upper portion 21c of the first conductive structure 21, and the first doped layer 32. In some embodiments, after the planarization process, the first upper portion 21c and the two ends of the first doped layer 32 are exposed. In some embodiments, two ends of the first doped layer 32 are made coplanar with the first surface 101a of the substrate 101.

The method 500 continues with operations 508 and 509. Operation 508 includes forming a first isolation structure 35 surrounded by the first conductive structure 21. Operation 509 includes forming a second isolation structure 37 coupled to the first conductive structure 21. In some embodiments, operation 508 further includes forming a third isolation structure 39 surrounded by the first conductive structure 21 and disposed adjacent to the first isolation structure 35.

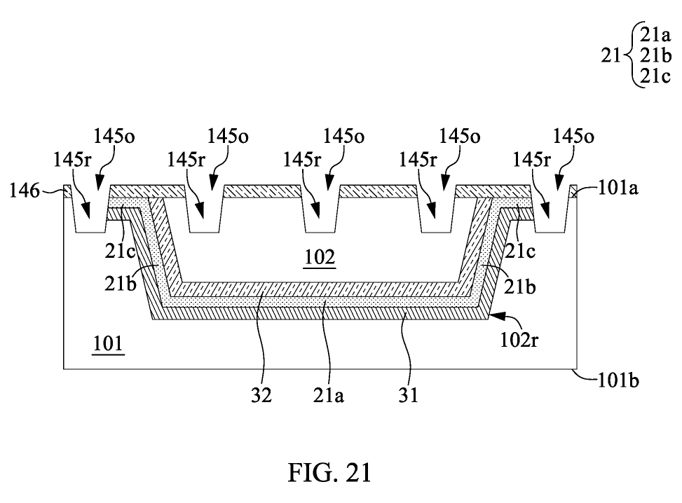

Referring to FIG. 21, in accordance with some embodiments, a mask layer 145 having a plurality of openings 145o is formed over the first surface 101a, the first conductive structure 21, the first doped layer 32, and the semiconductor material layer 102, and recesses 145r are formed using the mask layer 145 as a removal template. In some embodiments, some of the recesses 145r are offset from the first conductive structure 21, and some of the recesses 145r are formed over the first conductive structure 21. In some embodiments, a portion of the semiconductor material layer 102 and a portion of the substrate 101 are removed.

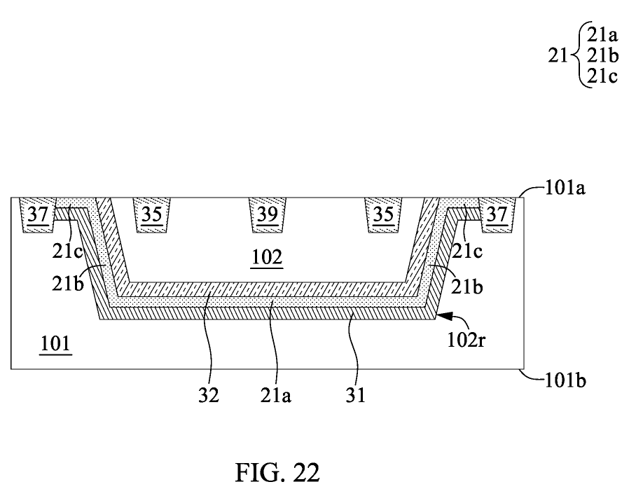

Referring to FIG. 22, a plurality of first isolation structures 35 are formed adjacent to the first sidewall portion 21b, a plurality of second isolation structures 37 are formed adjacent to the first conductive structure 21, and a third isolation structure 39 is formed between the first isolation structures 35. The first isolation structures 35 are surrounded by the first conductive structure 21. The plurality of second isolation structures 37 are coupled to the first conductive structure 21. In some embodiments, an isolation material is disposed in the recesses 145r, and the first isolation structures 35, the second isolation structures 37 and the third isolation structure 39 are formed simultaneously. In some embodiments, a planarization process, such as a CMP process or a mechanical grinding process, is performed to planarize top surfaces of the semiconductor material layer 102, the substrate 101, the first upper portion 21c of the first conductive structure 21, the first doped layer 32, the first isolation structures 35, the second isolation structures 37 and the third isolation structure 39.

The method 500 continues with operation 510. Operation 510 includes doping the semiconductor material layer 102 in the recess 102r to form a doped semiconductor material layer 102d. In some embodiments, operation 510 of the method 500 is similar to operation 305 of the method 300.

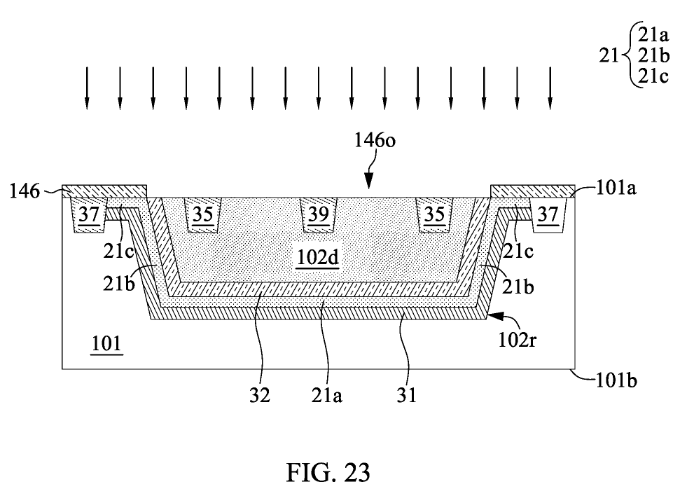

In some embodiments, referring to FIG. 23, a mask layer 146 having an opening 146o is formed over the first surface 101a, the first conductive structure 21 and the second isolation structures 37. In some embodiments, operation 510 includes forming the doped semiconductor material layer 102d. In some embodiments, the doped semiconductor material layer 102d is formed over and conformal to the first doped layer 32. The first doped layer 32 surrounds the doped semiconductor material layer 102d.

In some embodiments, the doped semiconductor material layer 102d is formed by introducing an impurity into the semiconductor material layer 102. The impurity may be a p-type dopant, such as at least one of boron, BF₂, aluminum, gallium, indium, and other suitable p-type dopants. The impurity may be an n-type dopant, such as at least one of phosphorous, arsenic, and other suitable n-type dopants. In some embodiments, the doped semiconductor material layer 102d and the first doped layer 32 have a same conductivity type. In some embodiments, the doped semiconductor material layer 102d and the first doped layer 32 have a second doping type, such as n-type. A depth of the doped semiconductor material layer 102d is determined by a level of energy used to perform the implantation process. For example, in an embodiment, n-type dopants are implanted at a dose of about 10¹² to about 10¹⁴ atoms/cm² and at an energy of about 50 KeV to about 1500 KeV. In some embodiments, the dosage of the formation of the first doped layer 32 are greater than the dosage of the formation of the doped semiconductor material layer 102d, respectively.

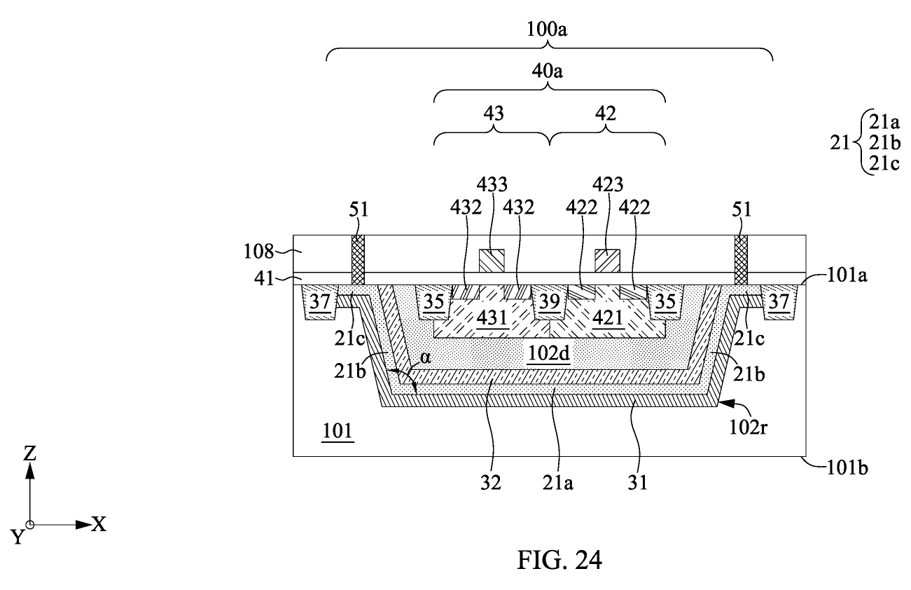

The method 500 continues with operation 511. Operation 511 includes forming a semiconductor device 40a over the doped semiconductor material layer 102d, wherein at least a portion of the semiconductor device 40a is surrounded by the first conductive structure 21. In some embodiments, operation 511 of the method 500 is similar to operation 306 of the method 300. Referring to FIG. 24, the semiconductor device 40a is formed over the first conductive structure 21, and at least a portion of the semiconductor device 40a is surrounded by the doped semiconductor material layer 102d. In some embodiments, the formation of the semiconductor device 40a includes disposing an oxide layer 41 over the first conductive structure 21, the first doped layer 32, the doped semiconductor material layer 102d and the first surface 101a of the substrate 101. In some embodiments, the first doped layer 32 is enclosed by the oxide layer 41 and the first conductive structure 21. The oxide layer 41 may be deposited by PVD, CVD, sputter deposition, or another technique for depositing the selected material.

In some embodiments, the semiconductor device 40a includes a CMOS device, and a PMOS device 42 and an NMOS device 43 are formed. In some embodiments, formation of the semiconductor device 40a includes forming an n-well region 421 under and between one of the first isolation structures 35 and the third isolation structure 39, forming p-type source/drain regions 422 in the n-well region 421, and forming a gate structure 423 over the n-well region 421. In some embodiments, the formation of the semiconductor device 40a further includes forming a p-well region 431 under and between one of the first isolation structure 35 and the third isolation structure 39, forming n-type source/drain regions 432 in the p-well region 431, and forming a gate structure 433 over the p-well region 431.

In some embodiments, the method 500 further includes disposing an interlayer dielectric 108 over the oxide layer 41. In some embodiments, referring to FIG. 24, the interlayer dielectric 108 is disposed over the semiconductor device 40a and the first conductive structure 21. The interlayer dielectric 108 is disposed over the first surface 101a of the substrate 101. In some embodiments, the interlayer dielectric 108 is disposed by deposition, CVD or any other suitable operation.

In some embodiments, the method 500 further includes removing portions of the interlayer dielectric 108, and forming several contacts within resulting openings. In some embodiments, a first contact 51 is formed over and electrically coupled to the first conductive structure 21. In some embodiments, the first contact 51 extends through the oxide layer 41 and the interlayer dielectric 108. In some embodiments, the semiconductor structure 100a is completed.

One aspect of this disclosure relates to a semiconductor structure. The semiconductor structure includes a substrate having a first doping type, a first conductive structure disposed within the substrate and having a bottom portion and a sidewall portion disposed over and coupled to the bottom portion, a first isolation layer disposed under the first conductive structure and within the substrate, and a semiconductor device disposed over the first conductive structure and including an oxide layer disposed over a first surface of the substrate. The first conductive structure is partially enclosed by the oxide layer and the first isolation layer, at least a portion of the semiconductor device is surrounded by the sidewall portion of the first conductive structure, and the semiconductor device is separated from the first conductive structure.

One aspect of this disclosure relates to a semiconductor structure. The semiconductor structure includes a substrate having a surface, a conductive structure disposed within the substrate and having a first bottom portion, a first sidewall portion disposed over and coupled to the first bottom portion, and a first upper portion coupled to the first sidewall portion and exposed through the surface; and a semiconductor device disposed over and electrically connected to the conductive structure. The first sidewall portion is disposed between the first bottom portion and the first upper portion, and at least a portion of the semiconductor device is surrounded by the first sidewall portion of the conductive structure in a plan view.

An aspect of this disclosure relates to a method of manufacturing a semiconductor structure. The method includes providing a substrate having a surface; forming a recess on the surface of the substrate; forming a conductive structure within and conformal to the recess; forming a semiconductor material layer in the recess and over the conductive structure; doping the semiconductor material layer to form a doped semiconductor material layer; and forming a semiconductor device over the doped semiconductor material layer and electrically connected to the conductive structure. At least a portion of the semiconductor device is surrounded by the conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a first doping type;
a first conductive structure disposed within the substrate and having a bottom portion and a sidewall portion disposed over and coupled to the bottom portion;
a first isolation layer disposed under the first conductive structure and within the substrate; and
a semiconductor device disposed over the first conductive structure and including an oxide layer disposed over a first surface of the substrate,
wherein the first conductive structure is partially enclosed by the oxide layer and the first isolation layer, at least a portion of the semiconductor device is surrounded by the sidewall portion of the first conductive structure, and the semiconductor device is separated from the first conductive structure.

2. The semiconductor structure of claim 1, wherein the first conductive structure further includes an upper portion coupled to the sidewall portion, the sidewall portion is disposed between the bottom portion and the upper portion, and the upper portion is in contact with the oxide layer.

3. The semiconductor structure of claim 2, wherein the upper portion extends from the sidewall portion and away from the semiconductor device.

4. The semiconductor structure of claim 1, wherein an angle between the bottom portion and the sidewall portion is greater than 90°.

5. The semiconductor structure of claim 1, further comprising:
a first semiconductor material layer disposed between the first conductive structure and the semiconductor device,
wherein the semiconductor material layer has a second doping type opposite to the first doping type.

6. The semiconductor structure of claim 1, further comprising:
a second conductive structure disposed within the substrate and adjacent to the first conductive structure; and
a second semiconductor material layer disposed within the substrate and surrounded by the second conductive structure,
wherein the second semiconductor material layer has the first doping type, and the second conductive structure is electrically isolated from the first conductive structure.

7. The semiconductor structure of claim 6, further comprising:
a second isolation layer disposed under the second conductive structure,
wherein the second isolation layer is disposed between the second conductive structure and the substrate.

8. The semiconductor structure of claim 6, wherein the second conductive structure is sandwiched between and in contact with the substrate and the second semiconductor material layer.

9. The semiconductor structure of claim 1, further comprising:
a contact electrically connected to the first conductive structure,
wherein the contact extends through the oxide layer.

10. The semiconductor structure of claim 1, further comprising:
a first isolation structure disposed between the first conductive structure and the semiconductor device; and
a second isolation structure coupled to the first conductive structure,
wherein at least a portion of the first conductive structure is disposed between the first isolation structure and the second isolation structure in a plan view.

11. A semiconductor structure, comprising:
a substrate having a surface;
a conductive structure disposed within the substrate and having a first bottom portion, a first sidewall portion disposed over and coupled to the first bottom portion, and a first upper portion coupled to the first sidewall portion and exposed through the surface; and
a semiconductor device disposed over and electrically connected to the conductive structure,
wherein the first sidewall portion is disposed between the first bottom portion and the upper portion, and at least a portion of the semiconductor device is surrounded by the first sidewall portion of the conductive structure in a plan view.

12. The semiconductor structure of claim 11, further comprising:
a first isolation layer disposed under the conductive structure; and
a first doped layer disposed over the conductive structure and between the conductive structure and the semiconductor device,
wherein the conductive structure is disposed between the first isolation layer and the first doped layer.

13. The semiconductor structure of claim 11, wherein the conductive structure includes metal silicide.

14. The semiconductor structure of claim 11, wherein the conductive structure further includes a second bottom portion separated from the first bottom portion, a second sidewall portion disposed over and coupled to the second bottom portion, and a second upper portion coupled to the second sidewall portion and exposed through the surface.

15. The semiconductor structure of claim 14, further comprising:
a first semiconductor material layer in contact with the first bottom portion, the first sidewall portion and the first upper portion; and
a second semiconductor material layer having a first doping type and in contact with the second bottom portion, the second sidewall portion, the second upper portion and the first semiconductor material layer,
wherein the first semiconductor material layer has a second doping type opposite to the first doping type.

16. A method of manufacturing a semiconductor structure, comprising:
providing a substrate having a surface;
forming a recess on the surface of the substrate;
forming a conductive structure within and conformal to the recess;
forming a semiconductor material layer in the recess and over the conductive structure;
doping the semiconductor material layer to form a doped semiconductor material layer; and
forming a semiconductor device over the doped semiconductor material layer, wherein the semiconductor device is electrically connected to the conductive structure,
wherein at least a portion of the semiconductor device is surrounded by the conductive structure.

17. The method of claim 16, further comprising:
planarizing the semiconductor material layer, the conductive structure and the substrate before the formation of the semiconductor device,
wherein a top surface of the semiconductor material layer and a top surface of the conductive structure are made coplanar with the surface of the substrate.

18. The method of claim 16, further comprising:
forming a first isolation layer in the recess before the formation of the conductive structure; and
forming a first doped layer in the recess and over the conductive structure before forming the semiconductor material layer,
wherein the conductive structure is formed between the first isolation layer and the first doped layer.

19. The method of claim 16, wherein the formation of the conductive structure includes:
forming a second doped layer in the recess; and
annealing the substrate to drive the second doped layer to the conductive structure.

20. The method of claim 16, further comprising:
forming a first isolation structure surrounded by the conductive structure;
forming a second isolation structure coupled to the conductive structure; and
electrically coupling a contact to the conductive structure,
wherein the first isolation structure is disposed between the conductive structure and the semiconductor device, and the contact is disposed between the first isolation structure and the second isolation structure in a plan view.
